(19) United States
(12) Patent Application Publication
(10) Pub. No.: US 2011/0217224 A1
(43) Pub. Date: Sep. 8, 2011

(54) SILICON CARBIDE CRYSTAL, METHOD OF MANUFACTURING THE SAME, APPARATUS FOR MANUFACTURING THE SAME, AND CRUCIBLE

(75) Inventor: Taro NISHIGUCHI, Itami-shi (JP)

(73) Assignee: SUMITOMO ELECTRIC INDUSTRIES, LTD., Osaka-shi (JP)

(21) Appl. No.: 13/037,496

(22) Filed: Mar. 1, 2011

(30) Foreign Application Priority Data
Mar. 2, 2010 (JP) 2010-045373

(51) Int. Cl. C01B 31/36; C30B 23/06

(52) U.S. Cl. 423/345; 117/84; 118/726

(57) ABSTRACT

A method of manufacturing SiC crystal includes the following steps. A manufacturing apparatus including a crucible having a main body portion and a heat insulating material covering the main body portion is prepared. In the main body portion, seed crystal is arranged opposed to a source material. The source material is heated to sublime and a source gas is precipitated on the seed crystal, to thereby grow SiC crystal. The step of preparing the manufacturing apparatus includes the step of arranging a heat radiation portion higher in thermal conductivity than the heat insulating material on a side of an outer surface of the main body portion on a side of seed crystal and covering the entire outer surface of the main body portion on the side of the seed crystal with the heat radiation portion or with the heat radiation portion and the heat insulating material.

### BACKGROUND OF THE INVENTION

1. Field of the Invention

The present invention relates to silicon carbide (SiC) crystal, a method of manufacturing the same, an apparatus for manufacturing the same, and a crucible.

2. Description of the Background Art

SiC crystal has a wide band gap, and it is greater in maximum dielectric breakdown electric field and thermal conductivity than silicon (Si). Meanwhile, it is as high as Si in carrier mobility and it is also high in saturated drift velocity of electrons and reverse breakdown voltage. Therefore, SiC crystal is expected to be applied to a semiconductor device required to achieve higher efficiency, a higher reverse breakdown voltage and a greater capacity.

SiC crystal employed in such a semiconductor device and the like is manufactured, for example, with a sublimation method representing a vapor phase deposition method (for example, G. AUGUSTINE et al., “Physical Vapor Transport Growth and Properties of SiC Monocrystals,” Phys. stat. sol. (b) vol. 202 (1997), pp. 137-139 (Non-Patent Document 1)). FIG. 11 is a cross-sectional view schematically showing an SiC manufacturing apparatus disclosed in Non-Patent Document 1. An apparatus for manufacturing SiC crystal and a method for growing SiC crystal disclosed in Non-Patent Document 1 will be described with reference to FIG. 11.

As shown in FIG. 11, an SiC manufacturing apparatus disclosed in Non-Patent Document 1 includes a crucible 101 and a heat insulating material 121 covering an outer periphery of crucible 101. A source material 17 for SiC crystal is arranged in a lower portion of crucible 101. In an upper portion of crucible 101, seed crystal 11 is arranged opposed to source material 17. Heat insulating material 121 has an opening portion 121a formed to penetrate heat insulating material 121 as far as its outer periphery on the side of seed crystal 11 arranged in crucible 101 and an opening portion 121b formed to penetrate heat insulating material 121 as far as its outer periphery on the side of source material 17 arranged in crucible 101.

Source material 17 is heated in this state to a temperature at which source material 17 sublimes. As a result of this heating, source material 17 sublimes and a sublimation gas is generated, and SiC crystal grows on a surface of seed crystal 11 set at a temperature lower than source material 17.

### SUMMARY OF THE INVENTION

In a case where heat insulating material 121 has opening portion 121a on the side of seed crystal 11 as in Non-Patent Document 1 above, heat can escape at the time point of start of growth of SiC crystal and therefore the temperature of opening portion 121a is low. When the source gas that leaked from crucible 101 adheres, however, SiC crystal adheres to opening portion 121a because the temperature of opening portion 121a is low. Thus, opening portion 121a may be clogged. If opening portion 121a provided in heat insulating material 121 is clogged during growth, a growth condition changes. Thus, crystallinity of grown SiC crystal becomes poor.

Therefore, the present invention relates to SiC crystal, a method of manufacturing the same, an apparatus for manufacturing the same, and a crucible, capable of achieving good crystallinity of SiC crystal.

A method of manufacturing SiC crystal according to the present invention includes the following steps. A manufacturing apparatus including a crucible having a main body portion and a heat insulating material covering the main body portion is prepared. A source material is arranged in the main body portion. Seed crystal is arranged in the main body portion in a manner opposed to the source material. In the main body portion, SiC crystal is grown by heating the source material to sublime and precipitating a source gas on the seed crystal. The step of preparing a manufacturing apparatus includes the step of arranging a heat radiation portion higher in thermal conductivity than the heat insulating material on a side of an outer surface of the main body portion on a side of the seed crystal and covering the entire outer surface of the main body portion on the side of the seed crystal with the heat radiation portion or with the heat radiation portion and the heat insulating material.

An SiC crystal manufacturing apparatus according to the present invention is an apparatus for growing SiC crystal by causing a source material containing SiC to sublime and precipitating a source gas resulting from sublimation on seed crystal, including a crucible, a heat insulating material, a heat radiation portion, and a heating portion. The crucible includes a main body portion for arranging the source material and the seed crystal therein. The heat insulating material covers the main body portion. The heat radiation portion is arranged on a side of an outer surface of the main body portion on a side of the seed crystal and it is higher in thermal conductivity than the heat insulating material. The heating portion heats the inside of the main body portion. The entire outer surface of the main body portion on the side of the seed crystal is covered with the heat radiation portion or with the heat insulating material and the heat radiation portion.

According to the apparatus and the method for manufacturing SiC crystal in the present invention, the entire outer surface of the main body portion of the crucible on the side of seed crystal is covered with the heat radiation portion or with the heat radiation portion and the heat insulating material. Thus, introduction of a gas that leaked from the main body portion of the crucible in between the outer surface on the side of seed crystal and the heat radiation portion can be suppressed. In addition, since the heat radiation portion higher in thermal conductivity than the heat insulating material is arranged on the outer surface on the side of seed crystal, at a growth temperature of SiC crystal, heat of the crucible on the side of seed crystal can be dissipated to the outside as a result of high heat conduction. Thus, variation in a temperature of seed crystal during growth of SiC crystal can be suppressed. Since variation in a growth condition during growth of SiC crystal can thus be suppressed, good crystallinity of SiC crystal can be achieved.

In the method of manufacturing SiC crystal above, preferably, in the step of preparing a manufacturing apparatus, the heat radiation portion is arranged in contact with the outer surface of the crucible on the side of the seed crystal.

In the SiC crystal manufacturing apparatus above, preferably, the heat radiation portion is arranged in contact with the outer surface of the crucible on the side of the seed crystal.

Since heat received by the seed crystal can thus efficiently be dissipated to the outside, variation in a temperature of the seed crystal can be suppressed. Since variation in a growth condition during growth of SiC crystal can thus further be suppressed, better crystallinity of SiC crystal can be achieved.

In the method of manufacturing SiC crystal above, preferably, in the step of preparing a manufacturing apparatus, the heat radiation portion is arranged such that an outer periphery of the heat radiation portion and an outer periphery of the heat insulating material are located flush with each other.

In the SiC crystal manufacturing apparatus above, preferably, an outer periphery of the heat radiation portion and an outer periphery of the heat insulating material are located flush with each other.

Since a recess is thus not formed in a surface formed by the heat radiation portion and the heat insulating material, introduction of a gas that leaked from the crucible into this recess and resultant precipitation of crystal can be suppressed. Since variation in a growth condition during growth of SiC crystal can thus further be suppressed, better crystallinity of SiC crystal can be achieved.

In the method of manufacturing SiC crystal above, preferably, in the step of preparing a manufacturing apparatus, the heat radiation portion mainly composed of carbon (C) is prepared. In the SiC crystal manufacturing apparatus above, preferably, the heat radiation portion is mainly composed of C.

Since a heat radiation portion made of a material stable in an atmosphere in which SiC crystal is grown can thus be used, variation in a growth condition during growth of SiC crystal can be suppressed. Therefore, good crystallinity of manufactured SiC crystal can be achieved.

In the method and the apparatus for manufacturing SiC crystal above, preferably, the heat radiation portion is made of graphite.

Since graphite is stable at a high temperature, variation in a growth condition during growth of SiC crystal can further be suppressed. Therefore, better crystallinity of manufactured SiC crystal can be achieved.

In the method of manufacturing SiC crystal above, preferably, in the step of preparing a manufacturing apparatus, the heat radiation portion mainly composed of a metal is prepared. In the SiC crystal manufacturing apparatus above, preferably, the heat radiation portion is mainly composed of a metal.

Since a metal is high in thermal conductivity, it has a high heat radiation effect. Therefore, since heat received by the seed crystal can efficiently be dissipated to the outside, variation in a temperature of the seed crystal can be suppressed. Since variation in a growth condition during growth of SiC crystal can thus further be suppressed, better crystallinity of SiC crystal can be achieved.

In the method and the apparatus for manufacturing SiC crystal above, preferably, the metal is an alloy. Thus, a heat radiation portion having a wide range of physical properties can be formed and hence a higher effect is achieved.

In the method and the apparatus for manufacturing SiC crystal above, preferably, the heat radiation portion has a melting point not lower than 1800° C. Since the heat radiation portion is thus stable under a temperature condition for manufacturing SiC crystal, variation in a growth condition can further be suppressed. Therefore, better crystallinity of manufactured SiC crystal can be achieved.

SiC crystal according to the present invention is manufactured with the method of manufacturing SiC crystal described in any paragraph above. Since the SiC crystal according to the present invention is manufactured with variation in a growth condition during crystal growth being suppressed, good crystallinity can be achieved.

The SiC crystal above preferably has a polytype of 4H—SiC. Thus, a material for a device having a high reverse breakdown voltage can be realized.

A crucible according to the present invention is a crucible used for manufacturing SiC crystal, and it includes a main body portion for arranging a source material and seed crystal therein, and a heat radiation portion connected to an outer surface of the main body portion and protruding outward from the outer surface.

According to the crucible in the present invention, the heat insulating material lower in thermal conductivity than the heat radiation portion is at least arranged in a region where the heat radiation portion is not arranged, on the outer surface of the main body portion on the side of the heat radiation portion (where a seed substrate is arranged) when it is used for manufacturing SiC crystal, so that introduction of a gas that leaked from the crucible in between the heat radiation portion and the main body portion can be suppressed. In addition, by arranging seed crystal on an inner surface opposed to the heat radiation portion, heat of the main body portion on the side of the seed crystal can be dissipated to the outside as a result of high heat conduction by the heat radiation portion. Thus, variation in a temperature of the seed crystal during growth of SiC crystal can be suppressed. Since variation in a growth condition during growth of the SiC crystal can thus be suppressed, good crystallinity of the SiC crystal can be achieved.

In the crucible above, preferably, the main body portion and the heat radiation portion are mainly composed of C. Since the crucible made of a material stable in an atmosphere in which SiC crystal is grown can be used, variation in a growth condition during growth of the SiC crystal can be suppressed. Therefore, good crystallinity of manufactured SiC crystal can be achieved.

According to the SiC crystal, the method of manufacturing the same, the apparatus for manufacturing the same, and the crucible in the present invention, since the heat radiation portion is provided, variation in a growth condition during growth of SiC crystal can be suppressed and hence good crystallinity of the SiC crystal can be achieved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically showing SiC crystal in a first embodiment of the present invention.

FIG. 2 is a cross-sectional view schematically showing an SiC crystal manufacturing apparatus in the first embodiment of the present invention.

FIG. 3 is a cross-sectional view schematically showing a portion around a crucible of an SiC crystal manufacturing apparatus in a first variation of the first embodiment of the present invention.

FIG. 4 is a cross-sectional view schematically showing a portion around a crucible of an SiC crystal manufacturing apparatus in a second variation of the first embodiment of the present invention.

FIG. 5 is a cross-sectional view schematically showing a portion around a crucible of an SiC crystal manufacturing apparatus in a third variation of the first embodiment of the present invention.

FIG. 6 is a cross-sectional view schematically showing a crucible in a second embodiment of the present invention.

FIG. 7 is a cross-sectional view schematically showing a portion around a crucible of an SiC crystal manufacturing apparatus in the second embodiment of the present invention.

FIG. 8 is a cross-sectional view schematically showing a portion around a crucible of an SiC crystal manufacturing apparatus in a first variation of the second embodiment of the present invention.

FIG. 9 is a cross-sectional view schematically showing a portion around a crucible of an SiC crystal manufacturing apparatus in a second variation of the second embodiment of the present invention.

FIG. 10 is a cross-sectional view schematically showing a portion around a crucible of an SiC crystal manufacturing apparatus in a comparative example.

FIG. 11 is a cross-sectional view schematically showing a portion around a crucible of an SiC crystal manufacturing apparatus in Non-Patent Document 1.

### DESCRIPTION OF THE PREFERRED EMBODIMENTS

An embodiment of the present invention will be described hereinafter with reference to the drawings. In the drawings below, the same or corresponding elements have the same reference characters allotted and description thereof will not be repeated.

### First Embodiment

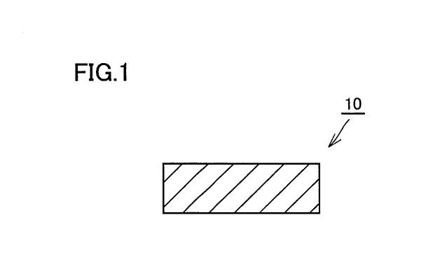

SiC crystal 10 in one embodiment of the present invention will initially be described with reference to FIG. 1. SiC crystal 10 has good crystallinity. Though a polytype of SiC crystal 10 is not particularly limited, it is preferably 4H—SiC.

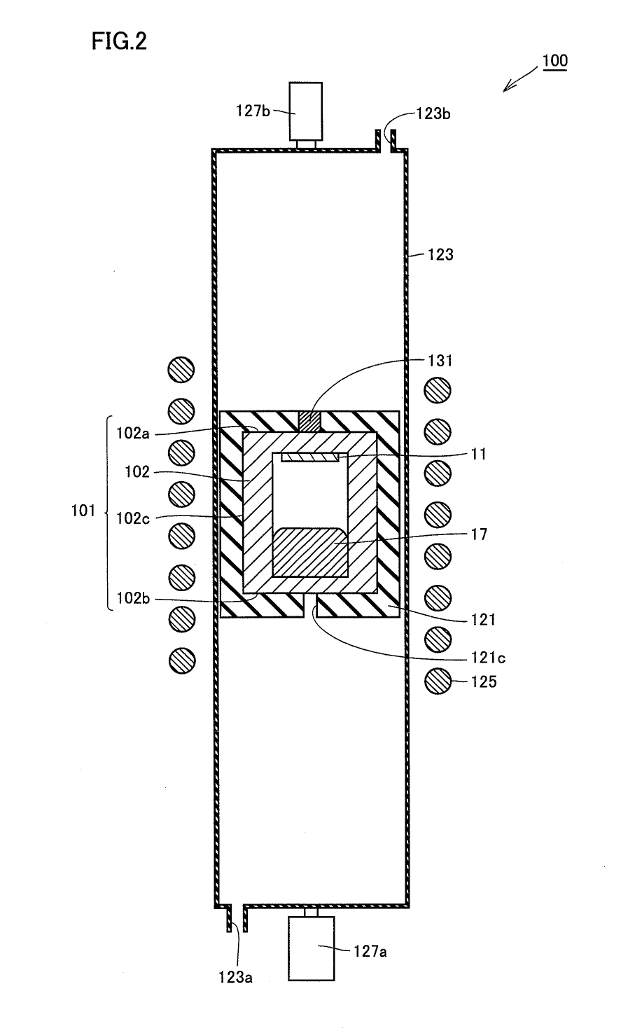

In succession, an SiC crystal manufacturing apparatus 100 in the present embodiment will be described with reference to FIG. 2. This manufacturing apparatus 100 is an apparatus for growing SiC crystal with a sublimation method. Namely, manufacturing apparatus 100 is an apparatus for growing SiC crystal 10 by causing a source material 17 containing SiC to sublime and precipitating a source gas resulting from sublimation on seed crystal 11.

As shown in FIG. 2, manufacturing apparatus 100 mainly includes a crucible 101 having a main body portion 102, a heat insulating material 121, a reaction vessel 123, a heating portion 125, and a heat radiation portion 131.

Crucible 101 includes main body portion 102. In the present embodiment, crucible 101 is formed by main body portion 102. Main body portion 102 has an inner surface and an outer surface. The outer surface of main body portion 102 has an outer surface 102a on the side of seed crystal 11, which is an upper surface, an outer surface 102b on the side of source material 17, which is a lower surface, and a side surface 102c. Main body portion 102 has seed crystal 11 and source material 17 arranged therein.

Preferably, main body portion 102 forming this crucible 101 is mainly composed of C, and more preferably it is composed mainly of C and remainder inevitable impurities. In this case, since crucible 101 is made of a material stable under a condition for growing SiC crystal, variation in a growth condition during growth of SiC crystal can be suppressed. Therefore, good crystallinity of manufactured SiC crystal can be achieved. Regarding such a material, crucible 101 is preferably composed, for example, of graphite. Since graphite is stable at a high temperature, crack of crucible 101 can be suppressed. In addition, C forming crucible 101 is a constituent element of SiC crystal. Therefore, even when crucible 101 sublimes and an element thereof is introduced into SiC crystal, such an element can be prevented from behaving as an impurity. Therefore, better crystallinity of manufactured SiC crystal can be achieved.

Heat insulating material 121 covers at least a part of the outer surface of this main body portion 102. In the present embodiment, heat insulating material 121 covers the outer surface of main body portion 102 except for the outer surface thereof on the side of seed crystal 11. Namely, heat insulating material 121 covers outer surface 102b of main body portion 102 on the side of source material 17 and side surface 102c.

Preferably, heat insulating material 121 is mainly composed of C, and more preferably it is composed mainly of C and remainder inevitable impurities. Regarding such a material, the heat insulating material is preferably composed, for example, of carbon felt. In this case as well, a heat insulating effect is achieved and variation in a growth condition during growth of SiC crystal can be suppressed. Therefore, good crystallinity of manufactured SiC crystal can be achieved. In addition, in the present embodiment, a temperature measurement hole 121c is formed in heat insulating material 121 on the side of source material 17.

Heat radiation portion 131 is arranged on the side of outer surface 102a of main body portion 102, on the side of seed crystal 11. Heat radiation portion 131 and heat insulating material 121 cover the entire outer surface 102a of main body portion 102 on the side of seed crystal 11. It is noted that heat radiation portion 131 alone may cover the entire outer surface 102a of main body portion 102 on the side of seed crystal 11.

In addition, preferably, the entire outer surface 102a on the side of seed crystal 11 and side surface 102c are covered with heat radiation portion 131 or with heat radiation portion 131 and heat insulating material 121. Since a temperature of main body portion 102 on the side of seed crystal 11 is lower than a temperature thereof on the side of source material 17, precipitation of crystal resulting from a gas that leaked from main body portion 102 is likely. Therefore, a region relatively low in temperature is preferably covered.

Heat radiation portion 131 is higher in thermal conductivity than a material forming heat insulating material 121. Thermal conductivity is a value measured, for example, with a laser flash method.

In addition, heat radiation portion 131 is preferably arranged in contact with outer surface 102a of main body portion 102 on the side of seed crystal 11. In other words, heat radiation portion 131 is preferably formed in contact with outer surface 102a opposed to the inner surface where seed crystal 11 is arranged in main body portion 102 (outer surface 102a on a back side of the surface where seed crystal 11 is arranged). In this case, an effect of high heat conduction by heat radiation portion 131 can further be exhibited.

Moreover, heat radiation portion 131 is preferably arranged such that an outer periphery of heat radiation portion 131 and an outer periphery of heat insulating material 121 are located flush with each other. Additionally, heat radiation portion 131 is preferably arranged in contact with outer surface 102a of main body portion 102 on the side of seed crystal 11. In this case, heat radiation portion 131 is arranged to penetrate heat insulating material 121 as far as the opposite side of outer surface 102a of main body portion 102. Namely, heat radiation portion 131 is formed to penetrate heat insulating material 121 as far as the outer periphery thereof, on the side of seed crystal 11 of main body portion 102. Thus, a heat radiation effect can further be exhibited.

Heat radiation portion 131 is higher in thermal conductivity than heat insulating material 121. Regarding such a material, heat radiation portion 131 is preferably mainly composed of C, and further preferably it is composed mainly of C and remainder inevitable impurities. In particular, heat radiation portion 131 is more preferably composed of graphite. In this case, heat of seed crystal 11 can be dissipated to the outside of manufacturing apparatus 100, heat resistance of the manufacturing apparatus can also be improved, and crystallinity of manufactured SiC crystal can also be improved. In addition, heat radiation portion 131 is preferably mainly composed of a metal, and further preferably it is composed mainly of a metal and remainder inevitable impurities. An alloy is suitably employed as the metal. For such a material, for example, tungsten (W), tantalum (Ta), and an alloy thereof are preferably employed. These materials are very high in thermal conductivity and also high in heat resistance.

Further, heat radiation portion 131 has a melting point preferably not lower than 1800° C., further preferably not lower than 2200° C., and still further preferably not lower than 2500° C. In this case, heat resistance can be maintained even in an atmosphere at a high temperature in which SiC crystal is manufactured.

Heat radiation portion 131 may include two or more layers. In this case, arrangement of each layer depending on difference in thermal conductivity is not particularly restricted.

Preferably, the center of heat radiation portion 131 and the center of crucible 101 (or main body portion 102) coincide with each other. In this case, variation in heat transfer in a lateral direction of seed crystal 11 can be suppressed.

Heat radiation portion 131 preferably includes the entire region defined by projecting arranged seed crystal 11 on outer surface 102a of main body portion 102 when viewed from the side of source material 17. In this case, an effect of enhancing in-plane uniformity of a temperature as a result of heat radiation from heat radiation portion 131 is high. It is noted that heat radiation portion 131 may include a partial region defined by projecting arranged seed crystal 11 on outer surface 102a of main body portion 102 when viewed from the side of source material 17, and it does not have to include the entire region. Alternatively, arranged seed crystal 11 may include the entire region defined by projecting heat radiation portion 131 on outer surface 102a of main body portion 102 when viewed from the side of source material 17.

Reaction vessel 123 is provided around heat insulating material 121 and heat radiation portion 131. At opposing end portions of reaction vessel 123, a gas introduction port 123a for feeding, for example, an atmospheric gas into reaction vessel 123 and a gas exhaust port 123b for exhausting the atmospheric gas to the outside of reaction vessel 123 are formed, respectively.

On an outer side of crucible 101 (in a central portion on an outer side of reaction vessel 123 in the present embodiment), heating portion 125 for heating the inside of crucible 101 is provided. Though heating portion 125 is not particularly limited, it is preferably implemented, for example, by a high-frequency heating coil or a resistance heater. In a case where the high-frequency heating coil is employed as heating portion 125, the high-frequency heating coil is preferably installed around the outer periphery of heat insulating material 121. In a case where the resistance heater is employed as heating portion 125, the resistance heater is preferably installed on the inner side of heat insulating material 121 and on the outer side of crucible 101.

On and under reaction vessel 123, radiation thermometers 127b and 127a for measuring temperatures in an upper portion and a lower portion of crucible 101 are provided, respectively. Radiation thermometer 127a conducts measurement through temperature measurement hole 121c formed in a part of heat insulating material 121 covering outer surface 102b of crucible 101 on the side of source material 17. Temperature measurement hole 121c may not be formed.

Though manufacturing apparatus 100 above may include various elements other than the above, illustration and description of these elements are not provided for the sake of convenience of the description.

In succession, a method of manufacturing SiC crystal in the present embodiment will be described with reference to FIGS. 1 and 2.

Initially, as shown in FIG. 2, manufacturing apparatus 100 including crucible 101 having main body portion 102 and heat insulating material 121 covering at least a part of the outer surface of main body portion 102 is prepared. This step includes the step of arranging heat radiation portion 131 higher in thermal conductivity than heat insulating material 121 on the side of outer surface 102a of main body portion 102 on the side of seed crystal 11 and covering the entire outer surface 102a of main body portion 102 on the side of seed crystal 11 with heat radiation portion 131 or with heat radiation portion 131 and heat insulating material 121. Namely, in this step, manufacturing apparatus 100 shown in FIG. 2 described above is prepared.

Specifically, heat radiation portion 131 is arranged in contact with outer surface 102a of main body portion 102 on the side of seed crystal 11. In addition, heat radiation portion 131 is arranged such that the outer periphery of heat radiation portion 131 and the outer periphery of heat insulating material 121 are located flush with each other. Moreover, heat radiation portion 131 mainly composed of C is prepared. Alternatively, heat radiation portion 131 mainly composed of graphite is prepared. Alternatively, heat radiation portion 131 mainly composed of a metal is prepared. Alternatively, heat radiation portion 131 mainly composed of an alloy is prepared. Further, heat radiation portion 131 having a melting point not lower than 1800° C. is prepared.

Then, as shown in FIG. 2, source material 17 is arranged in main body portion 102. Powders or a sintered body may be employed as source material 17, and for example, polycrystalline SiC powders or an SiC sintered body are (is) prepared. In the present embodiment, source material 17 is set in the lower portion of main body portion 102.

Then, as shown in FIG. 2, seed crystal 11 is arranged in main body portion 102 in a manner opposed to source material 17. In the present embodiment, seed crystal 11 is arranged in the upper portion of main body portion 102, in a manner opposed to source material 17. A crystal structure of seed crystal 11 is not particularly limited, and seed crystal 11 may have a crystal structure identical to or different from a crystal structure of SiC crystal to be grown. From a point of view of improving crystallinity of SiC crystal to be grown, SiC crystal identical in crystal structure is preferably prepared as seed crystal 11.

Then, in crucible 101, SiC crystal is grown by heating source material 17 to sublime and precipitating a source gas on seed crystal 11.

Specifically, source material 17 is heated by heating portion 125 to a temperature at which source material 17 sublimes. Though a heating method is not particularly limited, a high-frequency heating method or a resistance heating method is preferably employed. As a result of this heating, source material 17 sublimes and a sublimation gas (source gas) is generated. This sublimation gas is again solidified on the surface of seed crystal 11 set at a temperature lower than source material 17. By way of example of a growth temperature, for example, source material 17 is held at a temperature from 2300° C. to 2400° C., and seed crystal 11 is held at a temperature from 2100° C. to 2200° C. SiC crystal is thus grown on seed crystal 11.

In the step of growing SiC crystal, heat radiation portion 131 high in thermal conductivity can conduct heat from outer surface 102a of main body portion 102 on the side where seed crystal 11 is arranged to the outside of manufacturing apparatus 100. In addition, since the entire outer surface 102a of main body portion 102 on the side of seed crystal 11 is covered with heat insulating material 121 and heat radiation portion 131 or with heat radiation portion 131, deposition of SiC crystal in the inside of heat insulating material 121 and heat radiation portion 131 and in between heat radiation portion 131 and main body portion 102 can be suppressed even though growth of SiC crystal is continued. Therefore, variation in a growth condition such as variation in a temperature of seed crystal 11 during growth of SiC crystal can be suppressed. Thus, for example, SiC crystal having an intended polytype can be manufactured, that is, SiC crystal having good crystallinity can be grown.

Then, the inside of manufacturing apparatus 100 is cooled to a room temperature. Then, the manufactured SiC crystal is taken out of manufacturing apparatus 100. Thus, SiC crystal 10 (an SiC ingot) shown in FIG. 1 including seed crystal 11 and the SiC crystal formed on seed crystal 11 can be manufactured.

SiC crystal 10 shown in FIG. 1 may be manufactured by removing seed crystal 11 from the SiC ingot. In removal, seed crystal 11 alone may be removed, or seed crystal 11 and a part of the grown SiC crystal may be removed.

A removal method is not particularly limited, and for example, such a mechanical removal method as cutting, grinding or cleavage can be employed. Cutting refers to mechanical removal of at least seed crystal 11 from the SiC ingot by using a slicer having a peripheral cutting edge of an electrodeposition diamond wheel. Grinding refers to chipping away in a direction of thickness by bringing a grindstone in contact with a surface while it is turned. Cleavage refers to division of crystal along a crystal lattice plane. It is noted that a chemical removal method such as etching may be employed.

When manufactured SiC crystal 10 has a large thickness, SiC crystal 10 shown in FIG. 1 may be manufactured by cutting a plurality of slices of SiC crystal from the grown SiC crystal. In this case, cost for manufacturing SiC crystal 10 per one slice can be reduced.

Thereafter, one surface or opposing surfaces of the crystal may be planarized as necessary, by grinding, polishing or the like.

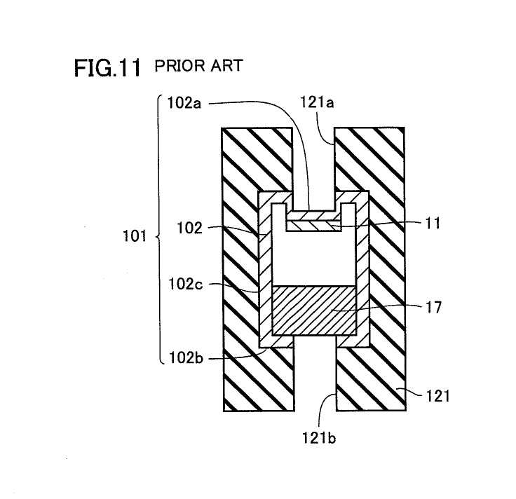

In succession, an effect of the method of manufacturing SiC crystal and manufacturing apparatus 100 in the present embodiment as compared with the methods and the apparatuses for manufacturing SiC crystal in a comparative example and Non-Patent Document 1 shown in FIGS. 10 and 11, respectively, will be described.

Initially, the SiC crystal manufacturing apparatus according to Comparative Example shown in FIG. 10 is basically similar in construction to manufacturing apparatus 100 in the present embodiment shown in FIG. 2, however, it is different in not including heat radiation portion 131. Namely, in the manufacturing apparatus according to Comparative Example, heat insulating material 121 covers the entire main body portion 102 including outer surface 102a on the side of seed crystal 11, outer surface 102b on the source material side, and side surface 102c.

In Comparative Example, even when heating is performed to set a temperature of the side of seed crystal 11 lower than a temperature of source material 17, the inside of main body portion 102 is heated to a high temperature and hence a temperature of seed crystal 11 also becomes gradually higher. Therefore, it becomes difficult to appropriately control a sublimation gas of source material 17 for precipitating the gas on the side of seed crystal 11, and hence growth of SiC crystal becomes difficult.

The SiC crystal manufacturing apparatus according to Non-Patent Document 1 shown in FIG. 11 is basically similar in construction to manufacturing apparatus 100 in the present embodiment shown in FIG. 2, however, it is different in that heat radiation portion 131 is implemented by opening portion 121a provided to penetrate heat insulating material 121.

In Non-Patent Document 1, in an early stage of growth of SiC crystal, heat can escape from opening portion 121a. Therefore, the temperature of seed crystal 11 located on the side of opening portion 121a is low. When a source gas that leaked from main body portion 102 flows in during growth of SiC crystal, however, crystal adheres to opening portion 121a because the temperature of opening portion 121a is low. Thus, opening portion 121a provided in heat insulating material 121 is clogged during growth of SiC crystal. Thus, a growth temperature of SiC crystal is varied during growth, which leads to poorer crystallinity, such as change in a polytype of grown SiC crystal from an intended polytype.

Meanwhile, according to SiC crystal manufacturing apparatus 100 and the manufacturing method in the present embodiment, the entire outer surface 102a of main body portion 102 on the side of seed crystal 11 is covered with heat insulating material 121 and heat radiation portion 131 high in thermal conductivity that are arranged on outer surface 102a of main body portion 102 on the side of seed crystal 11. Thus, introduction of a gas that leaked from crucible 101 in between heat radiation portion 131 and main body portion 102 can be suppressed. Therefore, deposition of crystal on the outer surface of main body portion 102 surrounded by heat insulating material 121 and heat radiation portion 131 can be suppressed during growth of SiC crystal. In addition, at a growth temperature of SiC crystal, heat of main body portion 102 on the side of seed crystal 11 can be dissipated to the outside of manufacturing apparatus 100 as a result of heat conduction. Namely, great heat radiation from crucible 101 through heat radiation portion 131 can be maintained. Since the temperature of seed crystal 11 can thus be prevented from becoming higher during growth of SiC crystal, the temperature of seed crystal 11 can be maintained lower than the temperature of source material 17. Namely, difference between the temperature of seed crystal 11 in the early stage of growth of SiC crystal and the temperature of seed crystal 11 in an intermediate (or a final) stage of growth can be made smaller in the present embodiment than in Non-Patent Document 1. Therefore, since variation in a growth condition such as variation in a temperature of seed crystal 11 during growth of SiC crystal can be suppressed, SiC crystal having good crystallinity can be manufactured.

(First Variation)

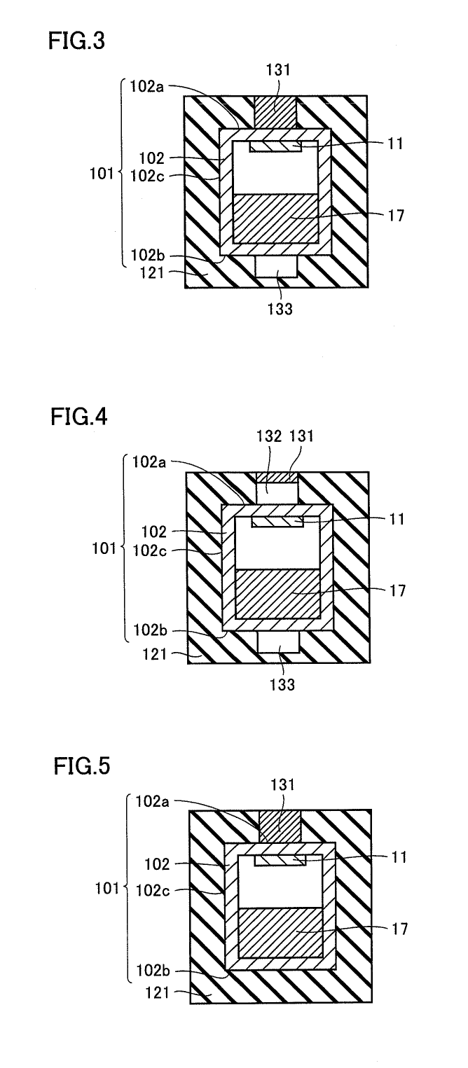

A first variation of SiC crystal manufacturing apparatus 100 in the present embodiment will be described with reference to FIG. 3. A manufacturing apparatus in the first variation shown in FIG. 3 is basically similar in construction to manufacturing apparatus 100 shown in FIG. 2, however, it is different in that a space 133 is further formed between outer surface 102b of main body portion 102 on the side of source material 17 and heat insulating material 121 and that temperature measurement hole 121c is not formed in heat insulating material 121.

(Second Variation)

A second variation of SiC crystal manufacturing apparatus 100 in the present embodiment will be described with reference to FIG. 4. A manufacturing apparatus in the second variation shown in FIG. 4 is basically similar in construction to the manufacturing apparatus in the first variation shown in FIG. 3, however, it is different in that a space 132 is arranged between outer surface 102a of main body portion 102 on the side of seed crystal 11 and heat radiation portion 131. Namely, space 132 is formed in contact with outer surface 102a opposed to the inner surface where seed crystal 11 is arranged in main body portion 102 (outer surface 102a on a back side of the surface where seed crystal 11 is arranged). In other words, space 132 is a space formed between main body portion 102 and heat radiation portion 131 covering outer surface 102a of main body portion 102 on the side of seed crystal 11.

Space 132 is filled with an atmospheric gas such as a nitrogen (N₂) gas, a helium (He) gas, an Argon (Ar) gas, or the like during growth of SiC crystal.

In the present variation, space 132 on outer surface 102a of main body portion 102 on the side of seed crystal 11 is covered with heat radiation portion 131. Thus, introduction of a gas that leaked from main body portion 102 into space 132 can be suppressed. Therefore, clogging of space 132 during growth of SiC crystal can be suppressed. As space 132 can be maintained, at a growth temperature of SiC crystal, heat of main body portion 102 on the side of seed crystal 11 can be dissipated to the outside of the manufacturing apparatus as a result of heat conduction by radiation. Therefore, in the present variation, in addition to the effect of good heat conduction by heat radiation portion 131, the effect of good heat conduction by space 132 can also be achieved. Therefore, since variation in a temperature of seed crystal 11 during growth of SiC crystal can further be suppressed, variation in a growth condition during growth of SiC crystal can further be suppressed. According to the present variation, better crystallinity of SiC crystal can be achieved.

(Third Variation)

A third variation of SiC crystal manufacturing apparatus 100 in the present embodiment will be described with reference to FIG. 5. A manufacturing apparatus in the third variation shown in FIG. 5 is basically similar in construction to manufacturing apparatus 100 shown in FIG. 2, however, it is different in that temperature measurement hole 121c is not formed in heat insulating material 121.

### Second Embodiment

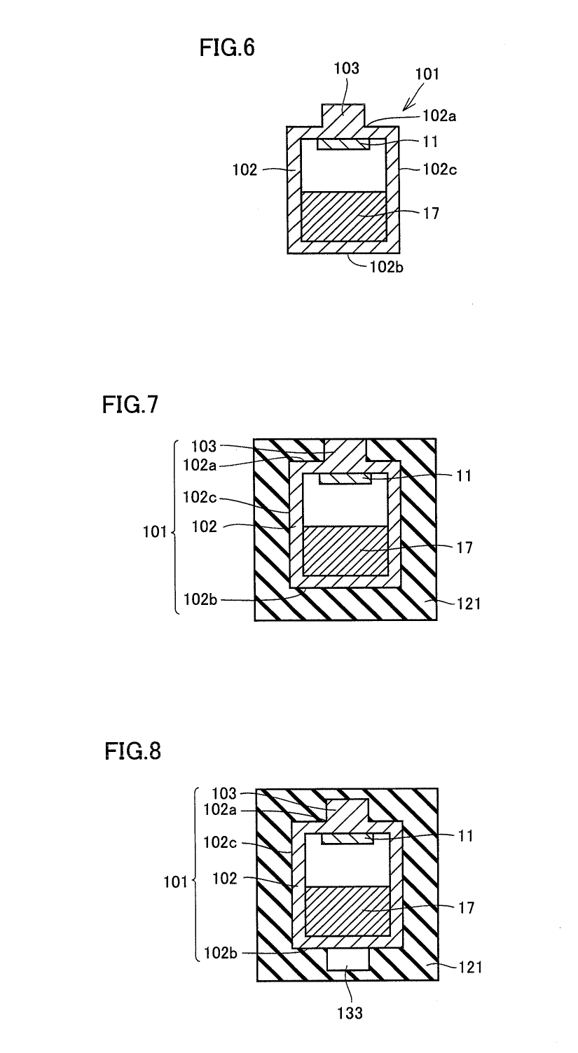

Crucible 101 in the present embodiment will be described with reference to FIG. 6. Crucible 101 in the present embodiment is used for manufacturing SiC crystal.

Crucible 101 includes main body portion 102 for arranging source material 17 and seed crystal 11 therein and a protruding portion 103 connected to outer surface 102a of main body portion 102 and protruding outward from outer surface 102a (upward in the present embodiment).

Main body portion 102 is, for example, in a cylindrical shape. Protruding portion 103 is formed on the upper surface of main body portion 102. For example, protruding portion 103 is convex. This protruding portion 103 corresponds to heat radiation portion 131 of manufacturing apparatus 100 in the first embodiment.

Main body portion 102 and protruding portion 103 may integrally be molded, or separately formed members may be joined to each other. Protruding portion 103 is high in thermal conductivity, and a material the same as that for heat radiation portion 131 in the first embodiment can be employed. Therefore, description of a material for protruding portion 103 will not be repeated.

In succession, an SiC crystal manufacturing apparatus in the present embodiment will be described with reference to FIG. 7. As shown in FIG. 7, the SiC crystal manufacturing apparatus in the present embodiment is basically similar in construction to manufacturing apparatus 100 in the first embodiment shown in FIG. 2, however, it is different in that crucible 101 shown in FIG. 6 is provided and temperature measurement hole 121c is not formed in heat insulating material 121. Namely, in the manufacturing apparatus in the present embodiment, protruding portion 103 of crucible 101 serves as the heat radiation portion.

Specifically, as shown in FIG. 7, the manufacturing apparatus in the present embodiment includes crucible 101 having main body portion 102 and protruding portion 103 and heat insulating material 121. Protruding portion 103 is arranged on the side of outer surface 102a of main body portion 102 on the side of seed crystal 11, and it is higher in thermal conductivity than heat insulating material 121. Protruding portion 103 and heat insulating material 121 cover the entire outer surface of main body portion 102. Namely, protruding portion 103 covers outer surface 102a on the side of seed crystal 11, while heat insulating material 121 covers outer surface 102b on the side of source material 17 and side surface 102c.

The method of manufacturing SiC crystal in the present embodiment is basically similar in features to the method of manufacturing SiC crystal in the first embodiment, however, it is different in the step of preparing the manufacturing apparatus shown in FIG. 7.

(First Variation)

A first variation of the SiC crystal manufacturing apparatus in the present embodiment will be described with reference to FIG. 8. A manufacturing apparatus in the first variation shown in FIG. 8 is basically similar in construction to the manufacturing apparatus shown in FIG. 7, however, it is different in that the entire outer surface of crucible 101 is covered with heat insulating material 121, space 133 is further formed between outer surface 102b of main body portion 102 on the side of source material 17 and heat insulating material 121, and temperature measurement hole 121c is not formed in heat insulating material 121.

(Second Variation)

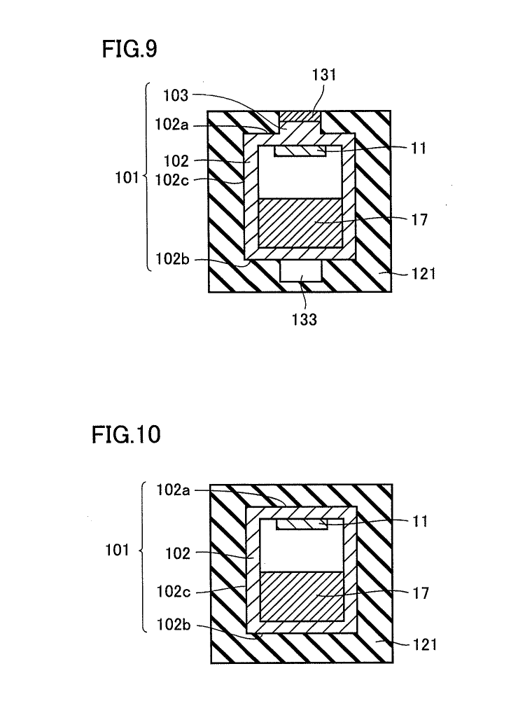

A second variation of the SiC crystal manufacturing apparatus in the present embodiment will be described with reference to FIG. 9. A manufacturing apparatus in the second variation shown in FIG. 9 is basically similar in construction to the manufacturing apparatus shown in FIG. 7, however, it is different in that heat radiation portion 131 is further arranged on protruding portion 103, space 133 is further formed between outer surface 102b of main body portion 102 on the side of source material 17 and heat insulating material 121, and temperature measurement hole 121c is not formed in heat insulating material 121. Since heat radiation portion 131 is similar to heat radiation portion 131 in the first embodiment, description thereof will not be repeated.

Protruding portion 103 and heat radiation portion 131 may be made of the same material or of different materials. In addition, protruding portion 103 and heat radiation portion 131 may be identical or different in thickness. Protruding portion 103, heat radiation portion 131 and heat insulating material 121 cover the entire outer surface 102a of main body portion 102 on the side of seed crystal 11.

### EXAMPLES

In the present example, heat radiation portion 131 higher in thermal conductivity than heat insulating material 121 was arranged on the side of outer surface 102a of main body portion 102 of crucible 101, on the side of seed crystal 11, and an effect of covering the entire outer surface 102a of main body portion 102 on the side of seed crystal 11 with heat insulating material 121 and heat radiation portion 131 was examined.

### Present Inventive Examples 1 to 3

In Present Inventive Examples 1 to 3, manufacturing apparatus 100 in the first embodiment described above and shown in FIG. 2 was employed to manufacture SiC crystal in accordance with the manufacturing method in the first embodiment described above.

Specifically, initially, crucible 101 made of graphite and having a hollow cylindrical shape was prepared. Crucible 101 had an outer diameter of 140 mm, an inner diameter of 120 mm, and a height of 100 mm.

In addition, three heat insulating sheets to serve as a heat insulating material, each having a thickness of 10 mm and made of carbon felt, were prepared. In each of the three heat insulating sheets, an opening portion having an outer diameter of 25 mm was formed. Then, the three heat insulating sheets each having the opening portion formed were stacked such that the opening portions coincide with one another, and arranged such that the opening portions were located on outer surface 102a of crucible 101 on the side of seed crystal 11. Here, the center of the opening portion and the center of crucible 101 coincided with each other.

Thereafter, heat radiation portion 131 made of a material shown in Table 1 below and having a shape permitting arrangement thereof in the opening portion (having an outer dimension of 25 mm and a thickness of 30 mm) was prepared. This heat radiation portion 131 was higher in thermal conductivity than the heat insulating sheet. This heat radiation portion 131 was arranged in the opening portion in heat insulating material 121. Thus, heat radiation portion 131 and heat insulating material 121 covered the entire outer surface 102a of main body portion 102 on the side of seed crystal 11.

It is noted that opening portion 121b penetrating heat insulating material 121 as far as the outer periphery was not formed on the side of source material 17 in crucible 101.

Crucible 101, heat radiation portion 131 and heat insulating material 121 were accommodated in reaction vessel 123, and a high-frequency heating coil serving as heating portion 125 was arranged around the outer periphery of reaction vessel 123.

In addition, source material 17 was arranged in the lower portion in crucible 101. SiC powders were employed as source material 17. Moreover, seed crystal 11 was arranged in the upper portion in crucible 101 in a manner opposed to source material 17. As seed crystal 11, 4H—SiC having an outer diameter of 75 mm was employed.

Then, an He gas at a flow rate of 0.5 slm and an N₂ gas at a flow rate of 0.1 slm were fed as an atmospheric gas into reaction vessel 123, and a temperature in crucible 101 was raised by using the high-frequency heating coil serving as heating portion 125. After a value indicated by radiation thermometer 127a for measuring a temperature of crucible 101 on the side of source material 17 reaches a defined growth temperature such as 2400° C., a pressure in crucible 101 was set to 20 Torr. Here, power of the high-frequency heating coil was controlled such that the temperature on the side of seed crystal 11 was set, for example, to 2200° C., which was lower than the temperature on the side of source material 17. Thus, an SiC gas was caused to sublime from source material 17, so that SiC crystal was grown on seed crystal 11 with a growth time period being set to 50 hours. The intended polytype was 4H—SiC. Thereafter, the temperature in manufacturing apparatus 100 was cooled to a room temperature. SiC crystal was thus manufactured.

### Comparative Example 1

The SiC crystal manufacturing apparatus and the manufacturing method in Comparative Example 1 were basically the same as those in Present Inventive Examples 1 to 3, however, they were different in that a heat insulating sheet was not provided with an opening portion but it was arranged on the crucible. Namely, in Comparative Example 1, a heat radiation portion was not arranged, as shown in FIG. 10.

### Comparative Example 2

The SiC crystal manufacturing apparatus and the manufacturing method in Comparative Example 2 were basically the same as those in Present Inventive Examples 1 to 3, however, they were different in that a heat radiation portion was not arranged in the opening portion formed in the heat insulating sheet. Namely, as shown in FIG. 11, an opening portion penetrating heat insulating material 121 was provided (a cavity was formed in outer surface 102a of crucible 101 on the side of seed crystal 11).

(Measurement Method)

A ratio of an area of the clogged heat radiation portion (opening portion) after growth of SiC crystal to an area of the heat radiation portion (opening portion) before growth of SiC crystal (a ratio of clogging) was calculated in connection with Comparative Example 2. Table 1 below shows the results.

In addition, 10 SiC crystal substrates were cut from the grown SiC crystal and they were visually observed as to whether a polytype other than 4H—SiC was generated or not. If there was only a single substrate of which color had changed, it was determined that a polytype other than 4H—SiC was generated and determination as polytype abnormality was made. The number of substrates among 10 SiC crystal substrates, in which polytype abnormality occurred, was counted. Table 1 below shows the results.

TABLE 1

| | Heat | | The Number of |
|---|---|---|---|
| | Radiation | Ratio of | Substrates Having |
| | Portion | Clogging | Polytype Abnormality |
| Present Inventive | Graphite | — | 0 |
| Example 1 | | | |
| Present Inventive | Tungsten | — | 0 |
| Example 2 | | | |
| Present Inventive | Tantalum | — | 0 |
| Example 3 | | | |
| Comparative | Not Provided | — | 10 |
| Example 1 | | | |
| Comparative | Cavity | More than 50% | 3 |
| Example 2 | | | |

(Measurement Results)

As shown in Table 1, according to manufacturing apparatus 100 and the manufacturing method in Present Inventive Examples 1 to 3 in which heat radiation portion 131 higher in thermal conductivity than heat insulating material 121 was arranged on outer surface 102a of crucible 101 on the side of seed crystal 11 and heat radiation portion 131 and heat insulating material 121 covered outer surface 102a of main body portion 102 of crucible 101, no crystal adhered in between heat radiation portion 131 and heat insulating material 121 and in between heat radiation portion 131 and crucible 101 during growth of SiC crystal for 50 hours. Since heat radiation portion 131 was higher in thermal conductivity than heat insulating material 121, heat on the side of seed crystal 11 could effectively be dissipated to the outside and hence variation in a growth condition during growth of SiC crystal could be suppressed. Therefore, no substrate having polytype abnormality was included in the SiC crystal substrates cut from the grown SiC crystal.

On the other hand, in Comparative Example 1 where a heat radiation portion was not provided on outer surface 102a of crucible 101 on the side of seed crystal 11, the temperature on the side of seed crystal 11 could not be maintained low. Therefore, no SiC crystal substrate having a normal polytype could be manufactured.

Further, in Comparative Example 2 where a heat insulating material having a penetrating opening portion is provided, at least a part of opening portion 121a serving as the heat radiation portion was clogged by crystal during growth of SiC crystal for 50 hours. Therefore, as a result of variation in a growth condition during growth, a substrate having polytype abnormality was included in the SiC crystal substrates cut from the SiC crystal.

From the foregoing, it could be confirmed that, according to the present example, SiC crystal having improved crystallinity can be manufactured by arranging heat radiation portion 131 higher in thermal conductivity than heat insulating material 121 on the side of outer surface 102a of main body portion 102 of crucible 101, on the side of seed crystal 11, and covering the entire outer surface 102a of main body portion 102 on the side of seed crystal 11 with heat insulating material 121 and heat radiation portion 131.

Though the embodiments and the examples of the present invention have been described as above, combination of the features in each embodiment and example as appropriate is also originally intended.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing silicon carbide crystal, comprising the steps of:
preparing a manufacturing apparatus including a crucible having a main body portion and a heat insulating material covering said main body portion;
arranging a source material in said main body portion;
arranging seed crystal in said main body portion in a manner opposed to said source material; and
growing silicon carbide crystal by heating said source material to sublime and precipitating a source gas on said seed crystal in said main body portion, and
said step of preparing a manufacturing apparatus including the step of arranging a heat radiation portion higher in thermal conductivity than said heat insulating material on a side of an outer surface of said main body portion on a side of said seed crystal and covering entire said outer surface of said main body portion on the side of said seed crystal with said heat radiation portion or with said heat radiation portion and said heat insulating material.

2. The method of manufacturing silicon carbide crystal according to claim 1, wherein
in said step of preparing a manufacturing apparatus, said heat radiation portion is arranged in contact with said outer surface of said main body portion on the side of said seed crystal.

3. The method of manufacturing silicon carbide crystal according to claim 1, wherein
in said step of preparing a manufacturing apparatus, said heat radiation portion is arranged such that an outer periphery of said heat radiation portion and an outer periphery of said heat insulating material are located flush with each other.

4. The method of manufacturing silicon carbide crystal according to claim 1, wherein
in said step of preparing a manufacturing apparatus, said heat radiation portion mainly composed of carbon is prepared.

5. The method of manufacturing silicon carbide crystal according to claim 4, wherein
said heat radiation portion is made of graphite.

6. The method of manufacturing silicon carbide crystal according to claim 1, wherein
in said step of preparing a manufacturing apparatus, said heat radiation portion mainly composed of a metal is prepared.

7. The method of manufacturing silicon carbide crystal according to claim 6, wherein
said metal is an alloy.

8. The method of manufacturing silicon carbide crystal according to claim 6, wherein
said heat radiation portion has a melting point not lower than 1800° C.

9. Silicon carbide crystal manufactured with the method of manufacturing silicon carbide crystal according to claim 1.

10. The silicon carbide crystal according to claim 9, having a polytype of 4H—SiC.

11. A crucible used for manufacturing SiC crystal, comprising:
a main body portion for arranging a source material and seed crystal inside; and
a heat radiation portion connected to an outer surface of said main body portion and protruding outward from said outer surface.

12. The crucible according to claim 11, wherein
said main body portion and said heat radiation portion are mainly composed of carbon.

13. A silicon carbide crystal manufacturing apparatus for growing silicon carbide crystal by causing a source material containing silicon carbide to sublime and precipitating a source gas resulting from sublimation on seed crystal, comprising:
a crucible including a main body portion for arranging said source material and said seed crystal inside;
a heat insulating material covering said main body portion;
a heat radiation portion higher in thermal conductivity than said heat insulating material, arranged on a side of an outer surface of said main body portion on a side of said seed crystal; and
a heating portion for heating inside of said main body portion, and
entire said outer surface of said main body portion on the side of said seed crystal being covered with said heat radiation portion or with said heat insulating material and said heat radiation portion.

14. The silicon carbide crystal manufacturing apparatus according to claim 13, wherein
said heat radiation portion is arranged in contact with said outer surface of said main body portion on the side of said seed crystal.

15. The silicon carbide crystal manufacturing apparatus according to claim 13, wherein
an outer periphery of said heat radiation portion and an outer periphery of said heat insulating material are located flush with each other.

16. The silicon carbide crystal manufacturing apparatus according to claim 13, wherein
said heat radiation portion is mainly composed of carbon.

17. The silicon carbide crystal manufacturing apparatus according to claim 16, wherein
said heat radiation portion is made of graphite.

18. The silicon carbide crystal manufacturing apparatus according to claim 13, wherein
said heat radiation portion is mainly composed of a metal.

19. The silicon carbide crystal manufacturing apparatus according to claim 18, wherein
said metal is an alloy.

20. The silicon carbide crystal manufacturing apparatus according to claim 18, wherein
said heat radiation portion has a melting point not lower than 1800° C.
